(19) United States
(12) Patent Application Publication
(10) Pub. No.: US 2016/0254427 A1
(43) Pub. Date: Sep. 1, 2016

(54) Optoelectronic Component and Method for Securing Same

(71) Applicant: OSRAM Opto Semicondoctors GmbH, Regensburg (DE)

(72) Inventors: Ulrich FREI, Obertraubling (DE); Stefan GRÖTSCH, Bad Abbach (DE); Norbert HÄFNER, Lappersdorf (DE); Kurt-Jürgen LANG, Regen (DE)

(21) Appl. No.: 15/027,420

(22) PCT Filed: Oct. 7, 2014
(86) PCT No.: PCT/EP2014/071400

§ 371 Date: Apr. 5, 2016

(30) Foreign Application Priority Data
Oct. 8, 2013 (DE) 10 2013 220 302.0

(51) Int. Cl. H01L 33/62; H01L 25/075

(52) U.S. Cl. CPC H01L 33/62; H01L 25/0753; H01L 2933/0066

(57) ABSTRACT

An optoelectronic component includes a light-emitting diode and a receiving device on which the light-emitting diode is received. The receiving device includes a securing device that has an adhesive to allow the receiving device to be adhered to a carrier which supports the receiving device. A method for processing an optoelectronic component, a method for equipping a carrier with an optoelectronic component, and a device for receiving an optoelectronic component are also disclosed.

This patent application is a national phase filing under section 371 of PCT/EP2014/071400, filed Oct. 7, 2014, which claims the priority of German patent application 10 2013 220 302.0, filed Oct. 8, 2013, each of which is incorporated herein by reference in its entirety.

### TECHNICAL FIELD

The invention relates to an optoelectronic component and to a method for processing an optoelectronic component. The invention relates furthermore to a method for equipping a carrier with an optoelectronic component and to a device for receiving an optoelectronic component.

### BACKGROUND

To allow them to work efficiently for an optical system, LEDs must generally be aligned or placed on a circuit board very precisely in relation to the optics and/or in relation to reference marks for the optics. This usually requires a considerable effort with respect to the tolerances on the circuit board, for example for drill holes, solder pads, the solder resist mask, but also an effort in the processing process itself. What is more, the LED may become tilted during the soldering process, which can lead to both optical and mechanical failures or to a poorer soldered connection.

There is therefore a need for an optoelectronic component comprising a light-emitting diode that can be securely placed on a circuit board without any displacement or tilting of the component occurring during a soldering process.

### SUMMARY

Embodiments of the invention provide an improved optoelectronic component that overcomes the aforementioned disadvantages and allows reliable fixing on a carrier.

Further embodiments provide a corresponding method for processing an optoelectronic component.

Further embodiments provide a corresponding method for equipping a carrier with the optoelectronic component according to the invention.

Further embodiments provide a device for receiving the optoelectronic component according to the invention that allows trouble-free storage and/or trouble-free transport.

According to one aspect, an optoelectronic component is provided, comprising: a light-emitting diode, a receiving device, at which the light-emitting diode is received, wherein the receiving device has a fixing device, wherein the fixing device comprises an adhesive substance in order to be able to adhesively attach the receiving device to a carrier carrying the receiving device.

According to another aspect, a method for processing an optoelectronic component is provided, comprising the following steps: providing an optoelectronic component, wherein the component has a light-emitting diode and a receiving device, at which the light-emitting diode is received, and applying a fixing device to the receiving device, wherein the fixing device has an adhesive substance in order to be able to adhesively attach the receiving device to a carrier carrying the receiving device.

According to a further aspect, a method for equipping a carrier with the optoelectronic component according to the invention is provided, comprising the steps of: arranging the optoelectronic component on the carrier and fixing the component with the carrier by means of the adhesive substance.

According to another aspect, a device for receiving the optoelectronic component according to the invention is provided, comprising: a tape with a number of containers, wherein the containers are designed for respectively receiving an optoelectronic component, wherein the containers respectively have a clearance, wherein the clearance is designed for contactlessly receiving the adhesive substance of the fixing device.

The invention therefore comprises in particular the idea of providing the receiving device that receives the light-emitting diode with an adhesive substance. Consequently, the optoelectronic component is advantageously designed and optimized for being able to be adhesively attached to a carrier. No further additional measures, for example, an adhesive substance on the carrier, are consequently required to bring about secure fixing of the optoelectronic component on the carrier. In particular, tilting of the component when it is arranged on the carrier can consequently be advantageously avoided. In particular, if after the adhesive bonding the optoelectronic component is soldered to the carrier, such tilting or displacement of the component in relation to the carrier is avoided.

According to the invention, an optoelectronic component that is already optimized for an adhesive-attachment operation or an adhesive-attachment process is provided.

The following technical effects and advantages are achieved in particular:

The provision of the adhesive creates an easy possible way of fixing the optoelectronic component on the carrier.

Consequently, there is advantageously no need for any additional effort to be expended for special machines that generally bring about the fixing of the component in relation to the carrier, for example, in that they keep the component in a predetermined position.

Furthermore, the tilting of the component in relation to the carrier is advantageously reduced or avoided.

The provision of the device for receiving the optoelectronic component comprising containers that respectively have a clearance, wherein the clearance is designed for contactlessly receiving the adhesive substance of the fixing device, advantageously brings about the effect that optoelectronic components can be reliably and securely stored and transported. This is because the components cannot become stuck in the container, because clearances that can contactlessly receive the adhesive substance of the fixing device are formed. This therefore means in particular that the adhesive substance does not have any contact with the clearance. This therefore means in particular that the adhesive substance does not have any contact with inside walls of the container, and consequently also does not have any contact with the clearance.

For the purposes of the present invention, an adhesive substance refers in particular to a process material that is used for the adhesive attachment. According to DIN EN 923, an adhesive substance is defined as a nonmetallic substance capable of joining components by surface bonding and internal strength. This definition is also used in particular as a basis for the term “adhesive substance” used here.

The term “adhesive substance” is used here in particular as a generic term. In particular, it covers all adhesive substances of the generic type. It is consequently also possible for different types of adhesive substances to be used. That applies in particular to an optoelectronic component. This therefore means in particular that the fixing device may have a number of different types of adhesive substances.

According to one embodiment, it may be provided that the carrier is formed as a circuit board. A circuit board may be referred to in particular as a printed circuit board. The circuit board or the printed circuit board preferably has drill holes and/or solder pads and/or solder resist masks and metallizations and/or electrical contacts.

According to one embodiment, it may be provided that the fixing device has a spacer, which is secured by a first end to the receiving device. An adhesive substance has been arranged at a second end that is opposite from the first end.

According to a further embodiment, it may be provided that the fixing device has a spacer, which is secured by a first end to the receiving device. An adhesive substance is arranged at a second end that is opposite from the first end.

The provision of a spacer advantageously brings about the effect that, when the receiving device is arranged on the carrier, a spacing from the carrier is formed with respect to the receiving device. This predetermined spacing from the carrier allows better degassing of a solder. In particular, it can in this way be prevented that a flux is trapped. As a result, a soldering process is advantageously improved. The spacers may be referred to in particular as feet, in particular as small feet.

It may preferably be provided that the spacer is secured by the first end to the receiving device, wherein the adhesive substance is subsequently arranged on the second end. This therefore means in particular that the spacer initially does not have any adhesive substance at the second end. It is arranged on the second end in particular after the spacer has been arranged on the receiving device.

According to one embodiment, it may be provided that the spacer has two legs extending parallel to one another, which are arranged spaced apart from one another. A portion connecting the two legs preferably extends perpendicularly in relation to the two legs. Here, the one leg forms the first end. The other leg forms the second end. For example, the spacer may have the form of an H, the form of a C or the form of a U.

According to one embodiment, it may be provided that the spacer is formed from the adhesive substance. This applies in particular in the case of a receiving device that is formed as a ceramic substrate or comprises such a substrate.

According to a further embodiment, it may be provided that the spacer is formed integrally with the receiving device. This therefore means in particular that the spacer and the receiving device form a common component. Consequently, the spacer may, for example, be advantageously formed along with the receiving device directly during the production of the receiving device. In this embodiment it may be provided that the adhesive substance is arranged on the second end after the production of the receiving device with the spacer.

According to one embodiment, it may be provided that the adhesive substance is applied to the second end of the spacer by means of transfer pads. This occurs, for example, by means of a pad printing process. This takes place in particular before the equipping, in particular directly before the equipping, of the carrier, in particular the circuit board or the printed circuit board, with the component.

According to one embodiment, it may be provided that the adhesive substance is already applied to the second end of the spacer during the processing or production of the optoelectronic component.

According to one embodiment, it may be provided that the spacer has been or is formed, in particular punched, from a double-sided adhesive tape. This therefore advantageously allows, for example, the spacer to be easily adhesively attached to the receiving device by its first end.

The provision of the spacer generally advantageously brings about the effect that the component can be pressed into a solder paste bed of a printed circuit board or a circuit board, so that the component can be fixed to the carrier, in particular the circuit board or printed circuit board, when the second end comes into contact with the adhesive substance.

A height of the spacer is preferably set here such that not only is there space for a printed solder paste (for example, with a thickness of about 120 μm), but also the molten solder is still in contact with the copper of the printed circuit board and the solder pads.

According to one embodiment, a number of spacers may be provided. The spacers may for example be formed as the same or, in particular, differently. This therefore means in particular that a spacer or a number of spacers is/are formed from the adhesive substance and that at the same time a spacer or a number of spaces is/are formed integrally with the receiving device.

According to one embodiment, it may be provided that a spacer is arranged at each corner of the receiving device; in particular, if the latter comprises a housing, at the corners of the housing.

According to a further embodiment, it may be provided that the receiving device comprises a housing. The housing may, for example, have a polygonal form, in particular a rectangular form. The light-emitting diode is preferably arranged in the housing, that is to say is preferably received by it.

According to one embodiment, it may be provided that the receiving device comprises a carrier component, on which the light-emitting diode is arranged. The carrier component may in particular have a polygonal form, in particular a rectangular form.

According to one embodiment, a number of light-emitting diodes, which, for example, may be formed as the same or preferably differently, may be provided.

According to one embodiment, it may be provided that the fixing device comprises a drop of adhesive substance. The drop may preferably be arranged in a clearance of the receiving device.

According to one embodiment, it may be provided that the receiving device is provided with a clearance before the application of the fixing device, wherein a drop of adhesive substance is subsequently arranged in the clearance.

This therefore means in particular that an adhesive substance drop, that is to say a drop of adhesive substance, has been or is introduced into the clearance of the receiving device. This advantageously brings about the effect that the component can, for example, be pressed into a solder paste bed and can be fixed when the adhesive substance drop comes into contact with the circuit board, generally the carrier. A height and/or an amount and/or a diameter of the drop is or has been set such that not only is there space for a printed solder paste (for example, with a thickness of about 120 μm), but also the molten solder is still in contact with the copper of the printed circuit board and the solder pads.

According to one embodiment, it may be provided that a number of clearances are or have been formed. The clearances may, for example, be formed as the same or, in particular, differently.

According to one embodiment, the clearance may have the form of an arc, in particular the form of an arc of a circle. Consequently, a drop of adhesive substance can fit into the clearance particularly well, and consequently stays there particularly reliably.

According to one embodiment, a number of drops of adhesive substance may have been or be provided. The drops may in particular be formed as the same, or preferably differently.

According to a further embodiment, a number of drops may have been or be arranged in a clearance. This brings about particularly reliable fixing of the receiving device on the carrier, in particular the circuit board.

If a number of clearances are provided, a respective number of drops of adhesive substance per clearance may in particular be different or preferably the same.

According to one embodiment, the clearance or the clearances may be or have been formed in a corner of the receiving device, in particular the carrier component or the housing.

According to one embodiment, the adhesive substance may be dispensed into the clearance, so that as a result a drop can form.

In another embodiment, an already ready-made drop of adhesive substance may be introduced into the clearance.

For example, the drop may only be applied to the receiving device, that is to say into the clearance, when the component is in the tape. For this, the tape, in particular the container, may have a number of clearances, through which the adhesive substance can be dispensed onto the component, that is to say into the clearance.

According to one embodiment, the containers of the tape respectively have a hole or clearance or a number of holes or clearances, through which an adhesive substance can be brought onto the receiving device. The hole or the holes are in particular formed in the clearance of the containers.

According to one embodiment, it may be provided that the clearances are or have been formed at corners of the receiving device.

According to one embodiment, it may be provided that the adhesive substance is a non-curing adhesive substance. This is of particular advantage in particular when a drop of adhesive substance is provided.

According to one embodiment, it may be provided that an adhesive substance is received in a drill hole of the receiving device, wherein the adhesive substance is designed to have a solid state of aggregation at a first temperature and to go over into a liquid state of aggregation at a second temperature, which is greater than the first temperature.

According to one embodiment, it may be provided that, before the application of the fixing device, the receiving device is provided with a drill hole, into which an adhesive substance is introduced, wherein the adhesive substance is designed to have a solid state of aggregation at a first temperature and to go over into a liquid state of aggregation at a second temperature, which is greater than the first temperature.

This therefore means in particular that the adhesive substance is initially solid at the first temperature and can only be liquefied after warming up to the second temperature. Thus, the component can be arranged on the carrier at the first temperature and still be displaced if necessary, since fixing by means of the adhesive substance has not yet been brought about. This is so because it is still solid at the first temperature. As soon as the target position of the component on the carrier has then been reached, the adhesive substance is warmed up to the second temperature. This advantageously brings about the effect that the adhesive substance runs out of the drill hole and establishes contact with the carrier. At the same time, the adhesive substance is still in contact with the receiving device, so that the adhesive substance contacts both the receiving device and the carrier. The adhesive substance is preferably subsequently cured. This advantageously brings about the effect that it cannot once again become liquid if warmed up beyond the second temperature, whereby it would then lose its adhesive force. This could happen, for example, in a soldering oven during a soldering process.

The first temperature may, for example, lie between 0° C. and 30° C. The second temperature may, for example, lie between 50° C. and 200° C. The adhesive substance is preferably solid under normal conditions according to DIN 1343, that is to say at a temperature of 273.15 K and a pressure of 131 325 Pa.

The curing of the adhesive substance may be effected, for example, by means of irradiation with blue (wavelength: 380 nm to 480 nm) light and/or ultraviolet (wavelength: 100 nm to 380 nm) light. The exact wavelength for the curing depends in particular on chemical properties of the adhesive substance. A correspondingly cured adhesive or a correspondingly cured adhesive substance consequently advantageously keeps the component in position in relation to the carrier during a soldering process, in particular during reflow soldering.

According to one embodiment, it may be provided that the drill hole is a conical drill hole. That is to say therefore in particular that the drill hole is formed as extending conically.

According to one embodiment, it may be provided that the warming is carried out by means of infrared radiation (wavelength: 780 nm to 1 mm). Consequently, just local warming with respect to the adhesive substance can be advantageously brought about (only the adhesive substance is warmed up, not its surroundings as well, or only insignificantly), without a solder paste being warmed up with it at the same time, which would lead to flux running. Warming may in particular also be brought about by means of exposure to a laser beam and/or one or more laser pulses.

According to one embodiment, the container has a bottom portion, on which the receiving device may rest or lies. Here, the bottom portion is of such a size that peripheral regions of the receiving device do not rest on the bottom portion, wherein the peripheral regions comprise the adhesive substance. The peripheral regions hover as it were in the air and are consequently received in the container without contact or contactlessly. For this, the bottom portion may go over into a clearance, also a container clearance, which may, for example, have a stepped form. The step forms space in which the adhesive substance is arranged.

According to one embodiment, the containers may, for example, be formed as the same or preferably differently.

### BRIEF DESCRIPTION OF THE DRAWINGS

The properties, features and advantages of this invention that are described above and the manner in which they are achieved become clearer and more clearly understandable in connection with the following description of the exemplary embodiments, which are explained in greater detail in connection with the drawings, wherein

FIG. 1, which includes FIGS. 1A-1E, shows a circuit board and an optoelectronic component;

FIG. 2, which includes FIGS. 2A-1D, shows the circuit board equipped with the optoelectronic component according to FIG. 1;

FIG. 3 shows a further optoelectronic component in an oblique plan view from above;

FIG. 4 shows the optoelectronic opponent according to FIG. 3 in an oblique plan view from below;

FIG. 5, which includes FIGS. 5A-5E, shows a circuit board and a further optoelectronic component;

FIG. 6, which includes FIGS. 6A-6D, shows the circuit board equipped with the optoelectronic component according to FIG. 5;

FIG. 7, which includes FIGS. 7A-7D, shows two devices for receiving an optoelectronic component;

FIGS. 8 to 10 respectively show a view of a circuit board equipped with an optoelectronic component at different points in time of a method for equipping a carrier with an optoelectronic component;

FIG. 11 shows a flow diagram of a method for processing an optoelectronic component; and

FIG. 12 shows a flow diagram of a method for equipping a carrier with an optoelectronic component.

In the text that follows, the same references may be used for the same features.

### DETAILED DESCRIPTION OF ILLUSTRATIVE EMBODIMENTS

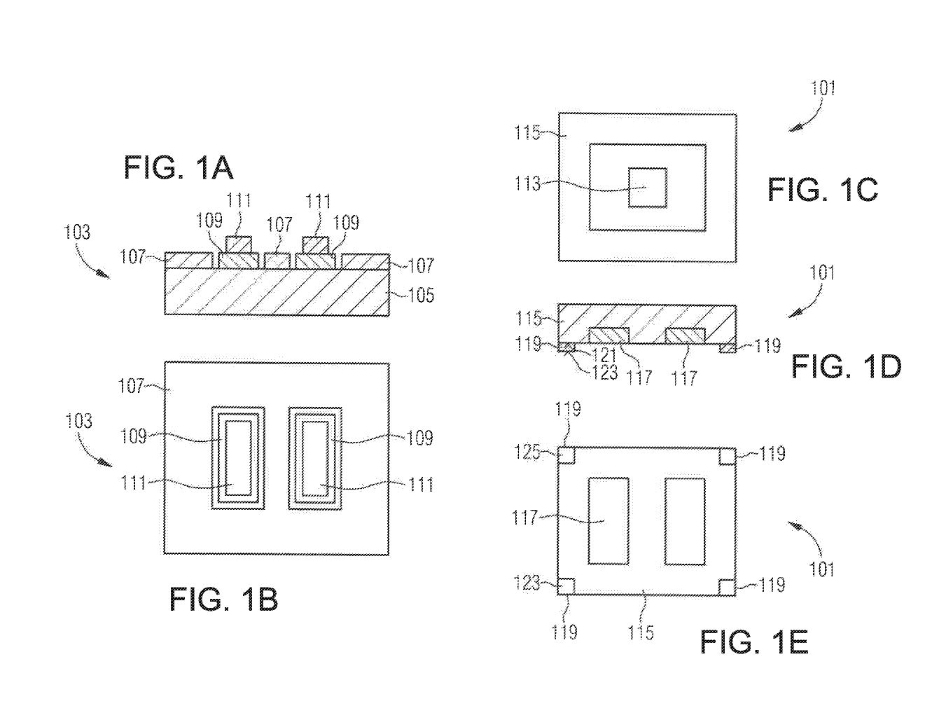

FIG. 1, which includes FIGS. 1A-1E, shows an optoelectronic component 101 and a circuit board 103.

The circuit board 103 is shown on the left side in a sectional view (FIG. 1A) and in a view from below (FIG. 1B).

The optoelectronic component 101 is shown on the right side in a plan view or view from above (FIG. 1C), a sectional view (FIG. 1D) and in a view from below (FIG. 1E).

The circuit board 103 has a substrate 105, which may also be referred to as a carrier substrate or circuit board substrate. This is so because such a substrate 105 of a circuit board 103 generally carries in a way known per se metallizations and/or electrical leads and/or electrical contacts. Thus, to this extent a number of solder resist masks 107 are formed spaced apart from one another on the substrate 105. Formed between the solder resist masks 107 are solder pads 109 (two of them). A solder paste 111 has been respectively applied to or is arranged on the two solder pads (109).

The configuration shown here with regard to the solder resist mask 107, the solder pads 109 and the solder paste 111 is merely to be regarded as an example. Depending on the application, other configurations are also possible.

The optoelectronic component 101 has one light-emitting diode 113, which is received by a receiving device 115. The receiving device 115 is formed as a housing, in which the light-emitting diode 113 is arranged. The receiving device 115 has a rectangular form.

Formed on an underside of the receiving device 115 are two regions 117, which comprise metallizations with solder pads. Electrical contacting of the light-emitting diode 113 is advantageously made possible by way of these two regions 117.

On the underside of the receiving device 115, a spacer 119 is respectively arranged or secured in the four corners of the underside of the receiving device 115. Here, the spacers 119 respectively have a first end 121 and a second end 123, which is opposite from the first end 121. The spacers 119 are secured by the first end 121 on the receiving device 115. An adhesive substance has been applied to or is arranged on a surface of the second end 123, which is facing away from the receiving device 115. This adhesive substance is symbolically identified by the designation 125, wherein, for the sake of clarity, not all of the second ends 123 of the spacers 119 have this designation, to clarify symbolically that an adhesive substance is provided here. The spacer 119 and the adhesive substance 125 form a fixing device.

In the exemplary embodiment shown according to FIG. 1, the spacers 119 have a rectangular form. Various other geometrical forms are possible. For example, a circular form may be provided.

The spacers 119 may be formed integrally with the receiving device 115. The spacers 119 may, for example, be formed as a separate component with respect to the receiving device 115. In this case, the spacers 119 are then adhesively attached or in some other way secured by their first end 121 to the receiving device 115, that is to say to its underside.

The optoelectronic component 101 with its configuration specifically shown in FIG. 1 is merely to be regarded as an example. Depending on the application, further possible configurations with respect to the two regions 117 may be provided. Also, a number of light-emitting diodes 113 may be provided. Instead of a housing, for example, a carrier component on which the light-emitting diode 113 is arranged may also be provided.

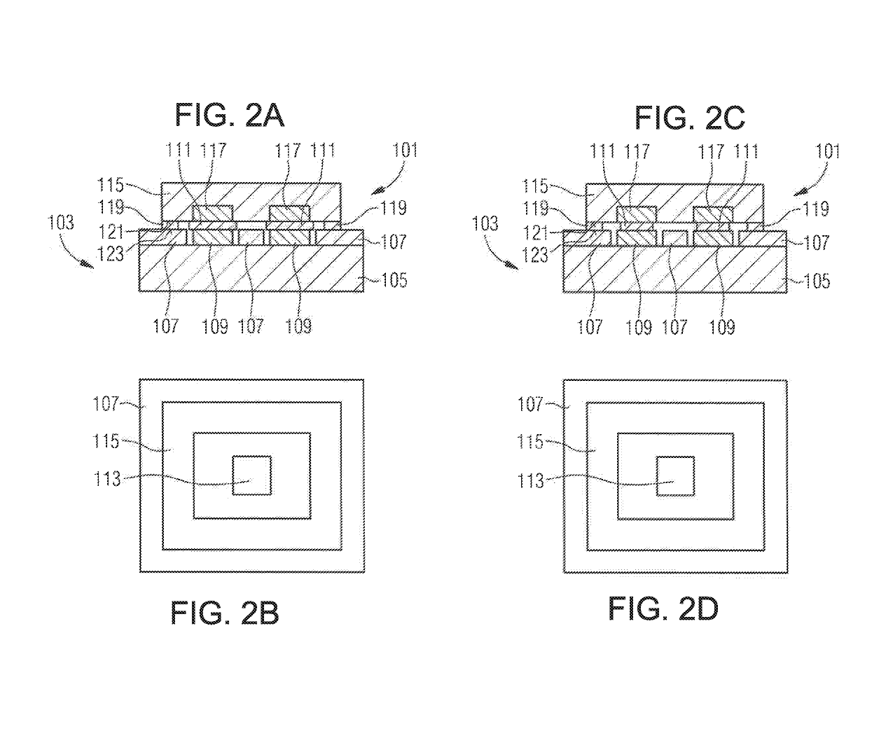

FIG. 2 shows the circuit board 103 equipped with the optoelectronic component 101.

In FIGS. 2A and 2B, the equipped circuit board 103 is shown before a soldering process. In FIGS. 2C and 2D, the equipped circuit board 103 is shown after a soldering process. The upper drawings according to FIGS. 2A and 2C show a sectional view. The drawings in FIGS. 2B and 2D show a plan view or view from above.

For equipping, the optoelectronic component 101 is set down in the solder pastes 111, whereby the second ends 123 make contact by their adhesive substance 125 with the solder resist masks 107. As a result, fixing by means of the adhesive substance 125 is therefore brought about. This is before the soldering process.

On account of this fixing on the basis of the adhesive substance 125, the optoelectronic component 101 cannot become tilted and/or be displaced during the soldering process. This is shown by the drawings on the right in FIG. 2, which includes FIGS. 2A-2D.

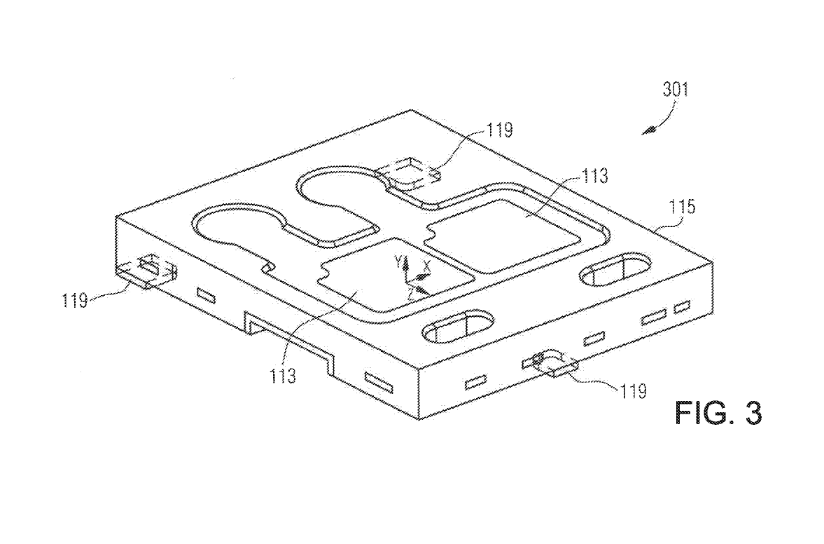

FIG. 3 shows a further optoelectronic component 301 in a plan view obliquely from above.

The optoelectronic component 301 comprises two light-emitting diodes 113, which are received by a receiving device 115. The receiving device 115 is formed as a carrier component on which the two light-emitting diodes 113 are arranged.

Provided with the designation 119, three spacers 119 are shown in a schematically indicated manner. However, they are normally not visible in the oblique plan view, and consequently are only depicted for the sake of clarity.

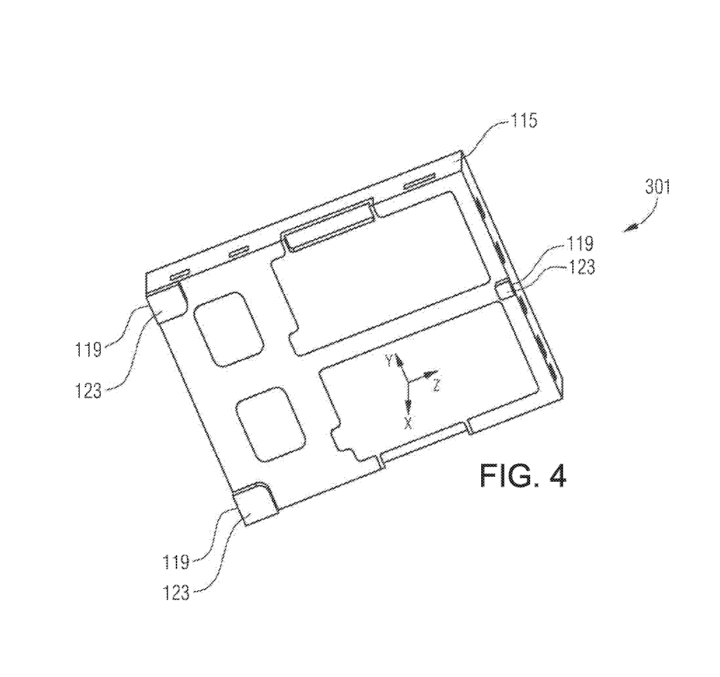

This is so because the three spacers 119 are arranged on an underside of the receiving device 115. This is shown by FIG. 4.

The three spacers 119 form an isosceles triangle. Here, two spacers 119 are arranged in two opposite corners of the receiving device 115. The third spacer is then correspondingly provided on a side of the receiving device 115 opposite from the two corners.

By this three-point arrangement of the three spacers 119, tilting of the optoelectronic component 301 when it has been mounted on a circuit board is advantageously made more difficult, or even avoided entirely, during a soldering process.

Although not explicitly shown, the three spacers 119 also have an adhesive substance on their side that is facing away from the receiving device 115. The spacers 119 with adhesive substance form a fixing device.

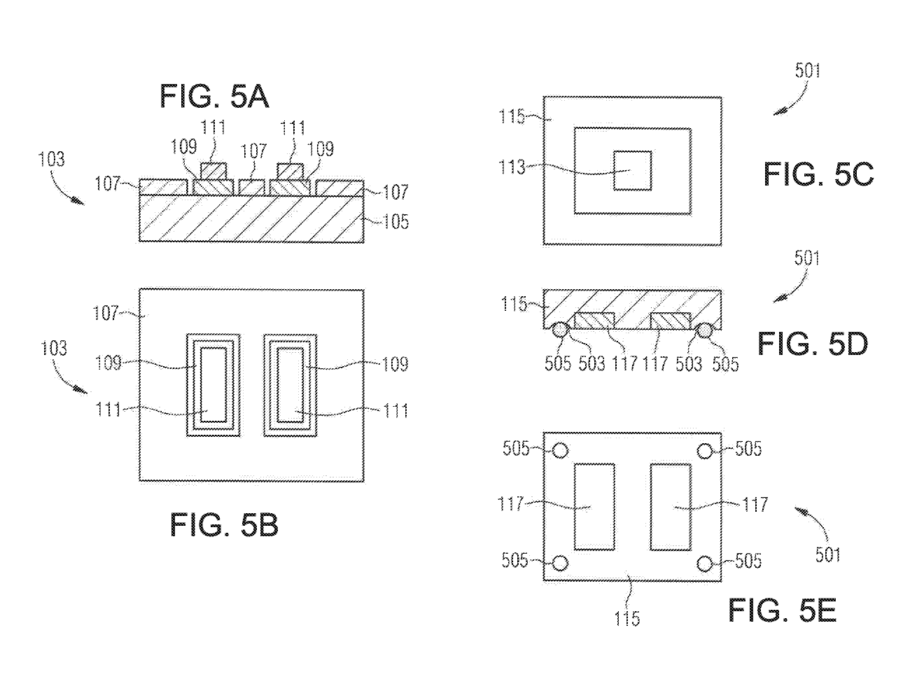

FIG. 5, which includes FIGS. 5A-5E, shows a circuit board 103 and another optoelectronic component 501.

The views and the structure of the circuit board 103 and the optoelectronic component 501 are substantially analogous to the exemplary embodiment shown in FIG. 1. Reference can be made to the corresponding statements.

As a difference, on its underside the receiving device 115 of the optoelectronic component 501 respectively has in the four corners a clearance 503, which has the form of an arc, in particular the form of a circle. A drop 505 of adhesive substance is respectively arranged or has been introduced into these arcuate clearances 503. The adhesive substance is preferably a non-curing adhesive substance. The drops 505 form a fixing device.

The clearances 503 are formed at the four corners of the underside of the receiving device 115.

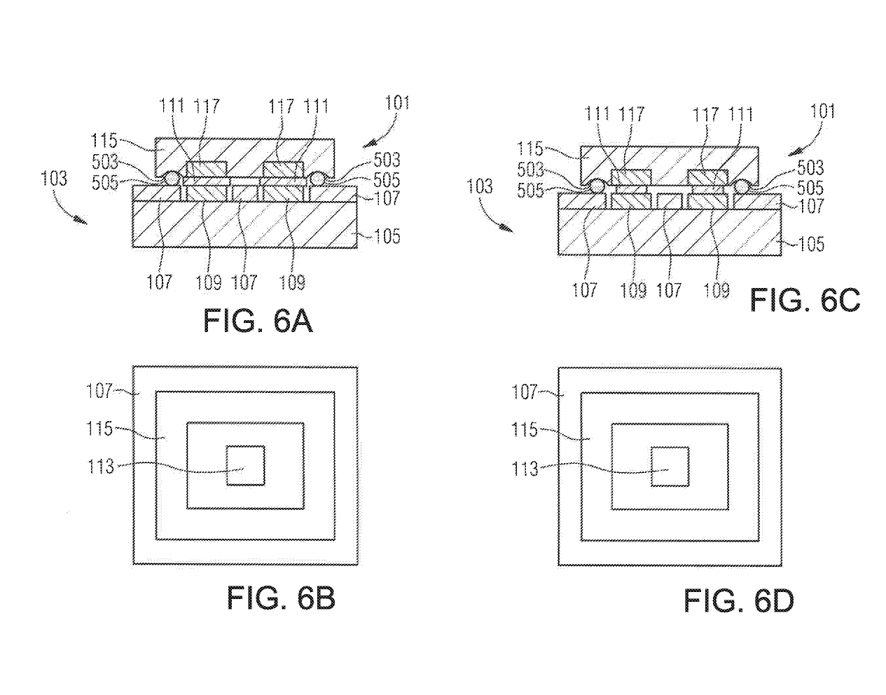

FIG. 6, which includes FIGS. 6A-6D, shows views analogous to the views according to FIG. 2. Reference can be made to the corresponding statements.

It can be clearly seen that, when the optoelectronic component 501 is set down on the circuit board 103, the four drops 505 of adhesive substance contact the solder resist masks 107, and consequently adhesively bond the receiving device 115 to the solder resist masks 107.

On the left side, the equipped circuit board 103 is shown before a soldering process. On the right side, the equipped circuit board 103 is shown after a soldering process.

On account of the four-point arrangement on the basis of the four drops 505 of adhesive substance, tilting of the optoelectronic component 501 during the soldering process is advantageously effectively prevented.

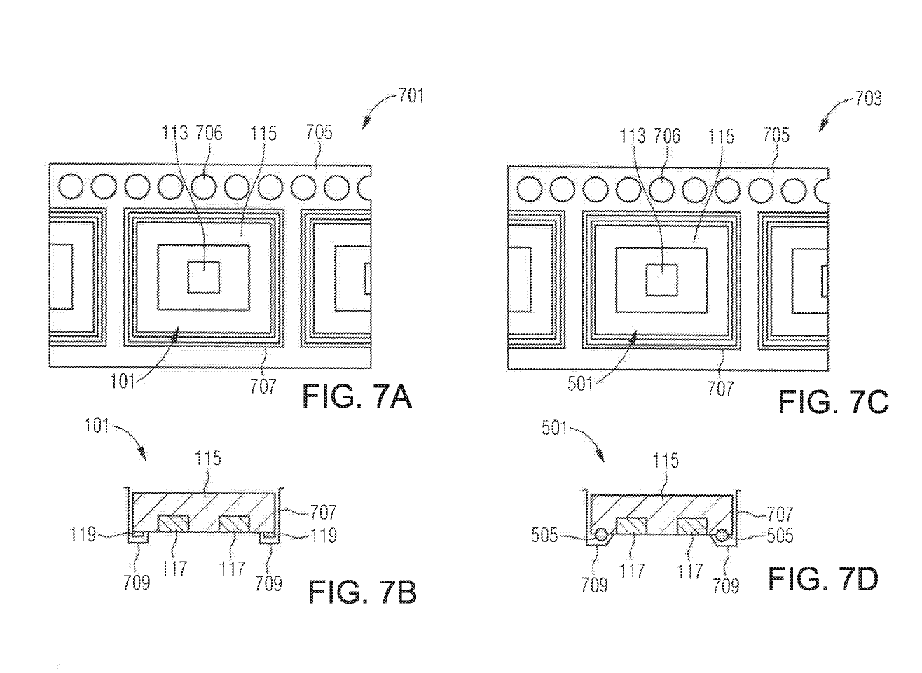

FIG. 7, which includes FIGS. 7A-7D, shows two devices 701 and 703 for receiving an optoelectronic component according to the present invention in a cut-off view. The upper drawings in FIGS. 7A and 7C show a plan view of the devices 701 and 703. The drawings lying thereunder (FIGS. 7B and 7D) show a sectional view of the devices 701 and 703.

The two devices 701 and 703 have substantially the same structure. They have in each case a tape 705, which respectively has perforations 706, whereby the tape 705 can be transported or moved by suitable transporting mechanisms. This is, for example, analogous to a film that is transported in a camera.

Each tape 705 has a number of containers 707, in which, for example, an optoelectronic component 101 according to FIG. 1 or an optoelectronic component 501 according to FIG. 5 may be respectively inserted.

For illustration, the component 101 according to FIG. 1 is inserted in the device 701 on the left. The component 501 according to FIG. 5 is inserted in the device 703 on the right.

For this, the containers 707 respectively have clearances 709, which are formed such that they can receive the adhesive substance of the components 101, 501 contactlessly. This therefore means in particular that the adhesive substance does not come into contact with the clearances 709, or further inside walls of the container 707, when the components have been received in the container 707.

The actual form of the clearances 709 depends in particular on the actual geometrical design of the fixing device of the components. To allow better distinction, the clearances 709 may also be referred to as container clearances.

Thus, for example, the containers 707 of the devices 701, 703 have in the bottom region four step-shaped clearances, the profile of which is preferably formed in a way approximately corresponding to the rectangular spacers 119 or the drops 505.

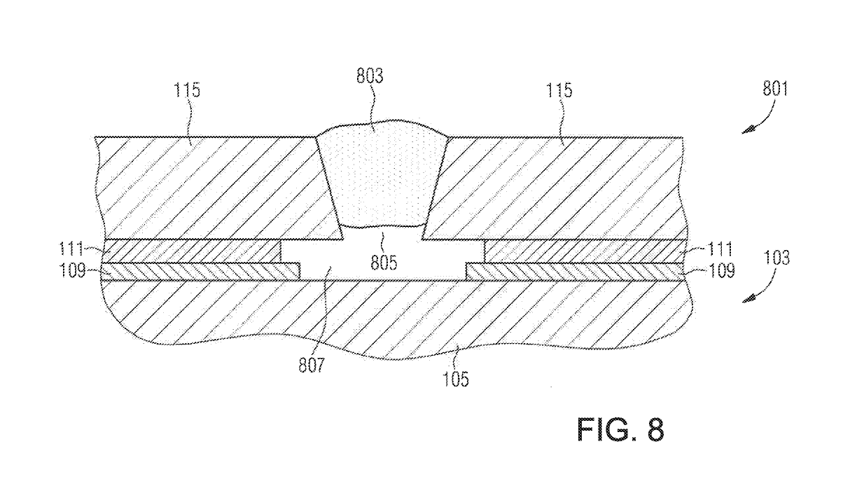

FIG. 8 shows another optoelectronic component 801 mounted on a circuit board 103.

The receiving device 115 has a conically extending drill hole 805, in which an adhesive substance 803 has been introduced. The adhesive substance 803 is solid, that is to say in a solid state of aggregation, under normal conditions (for example, standard conditions), in particular at a first temperature. At a second temperature, the adhesive substance 803 goes over into a liquid state of aggregation.

The optoelectronic component 801 is then to this extent mounted on the circuit board 103 in its position, as shown in FIG. 8, and pressed into the liquid solder paste 111. This advantageously creates a cavity 807 between the circuit board 103 and the receiving device 115.

For the sake of clarity, the regions 117 comprising metallizations with solder pads for the receiving device 115 are not shown.

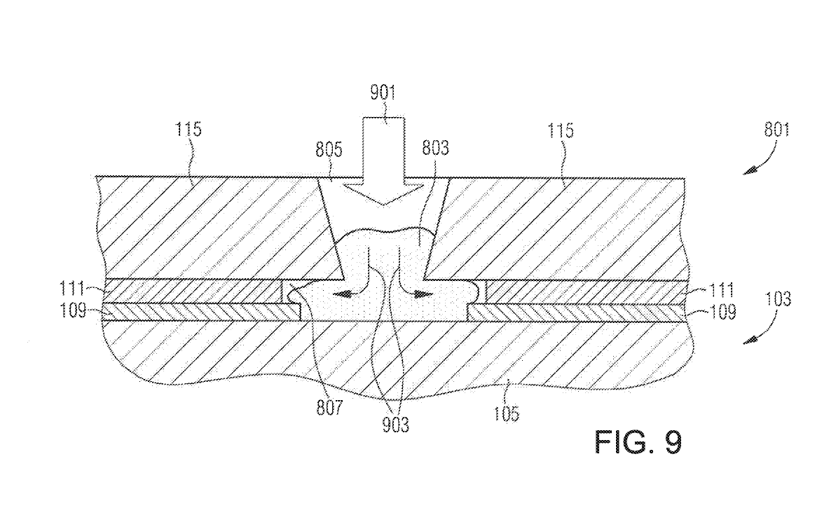

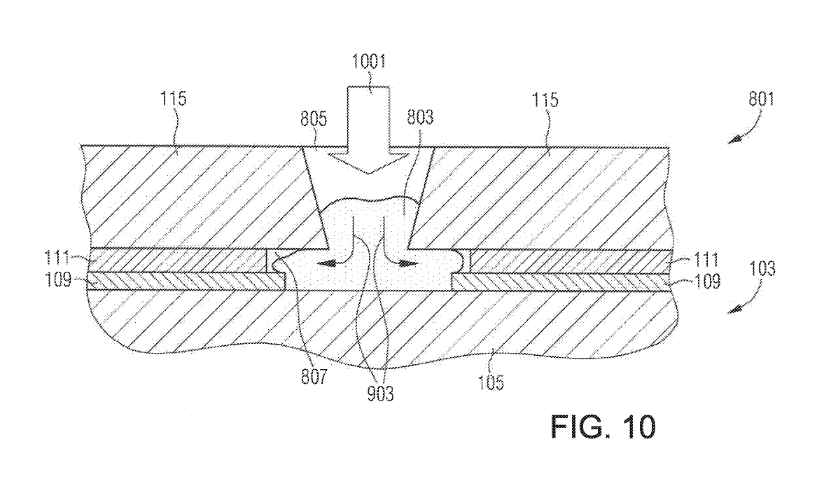

In the view according to FIG. 9, the adhesive substance 803 is warmed or heated up to the second temperature. This occurs in particular locally, so that the solder paste 111 is not warmed with it, or not significantly, and consequently a flux of the solder paste 111 cannot run. Local heating up or warming up may, for example, be carried out by means of infrared radiation. This exposure of the adhesive substance 803 to infrared radiation is symbolically identified by an arrow with the designation 901. Here, the infrared irradiation may also be carried out with a laser.

By warming the adhesive substance 803 up to the second temperature, at which the adhesive substance goes over from the solid state of aggregation into the liquid state of aggregation, the adhesive substance 803 runs into the cavity 807.

The running adhesive substance 803 consequently contacts both the receiving device 115 and the circuit board 103 with the substrate 105 and the solder pads 109.

As a result, good fixing is brought about by means of adhesive attachment.

Once the adhesive substance 803 has run, the adhesive substance 803 is cured. This occurs, for example, by ultraviolet irradiation or irradiation with blue light. The exact wavelength depends in particular on the adhesive substance 803 that is used. As a consequence of the curing, the adhesive substance 803 solidifies and thus brings about good fixing.

The irradiation with short-wave light, in particular blue or ultraviolet radiation, is symbolically identified by the designation 1001.

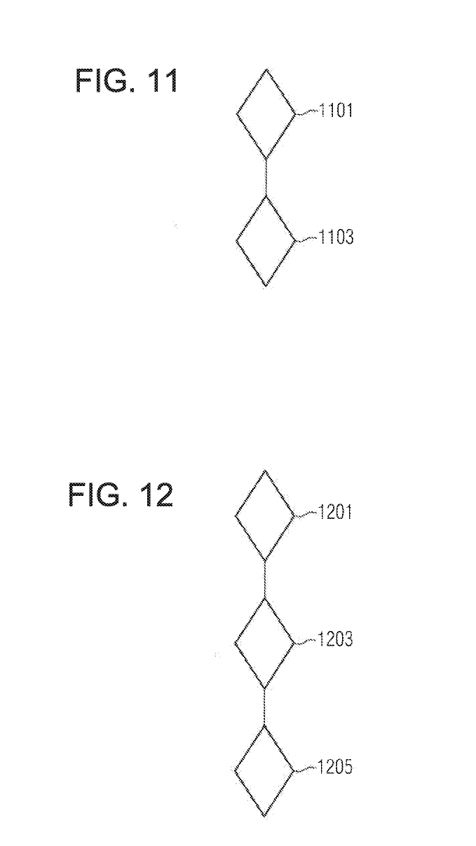

FIG. 11 shows a flow diagram of a method for processing an optoelectronic component.

According to a step 1101, an optoelectronic component is provided, wherein the component has a light-emitting diode and a receiving device, at which the light-emitting diode is received.

In a step 1103, a fixing device is applied to the receiving device, wherein the fixing device has an adhesive substance in order to be able to adhesively attach the receiving device to a carrier carrying the receiving device.

FIG. 12 shows a flow diagram of a method for equipping a carrier, in particular a circuit board, with the optoelectronic component 801 according to FIG. 8.

In a step 1201, the optoelectronic component 801 is arranged on the carrier, in particular on the circuit board. In a step 1203, after the arranging and before the fixing, the adhesive substance is warmed up to at least the second temperature. This advantageously brings about the effect that the adhesive substance liquefies and runs out of the drill hole and contacts both the carrier and the receiving device.

In a step 1205, subsequently, that is to say after the running of the adhesive substance, the adhesive substance is cured.

In further exemplary embodiments that are not shown, it may, for example, be provided that the carrier equipped in this way is further worked on or processed. In particular, a soldering process may be provided. For this, the equipped carrier may, for example, be passed through a reflow oven. The cured adhesive substance 803 has the effect that the component 801 is kept in its position and no longer made to float by wetting forces of the solder.

The invention can be applied in particular to high-power LEDs, LEDs in general, in particular if high precision is required in the mounting or equipping, optical sensors and infrared LEDs.

Although the invention has been more specifically illustrated and described in detail by the preferred exemplary embodiments, the invention is not restricted by the examples disclosed, and other variations may be derived from them by a person skilled in the art without departing from the scope of protection of the invention.

1-15. (canceled)

16. An optoelectronic component, comprising:
a light-emitting diode; and
a receiving device, at which the light-emitting diode is received, wherein the receiving device has a fixing device and wherein the fixing device comprises an adhesive substance in order to be able to adhesively attach the receiving device to a carrier carrying the receiving device.

17. The optoelectronic component as claimed in claim 16, wherein the fixing device has a spacer that is secured by a first end to the receiving device, and wherein an adhesive substance has been arranged at a second end that is opposite from the first end.

18. The optoelectronic component as claimed in claim 17, wherein the spacer is formed from the adhesive substance.

19. The optoelectronic component as claimed in claim 17, wherein the spacer is formed integrally with the receiving device.

20. The optoelectronic component as claimed in claim 16, wherein the fixing device comprises a drop of adhesive substance that is arranged in a clearance of the receiving device.

21. The optoelectronic component as claimed in claim 16, wherein an adhesive substance is received in a drill hole of the receiving device, wherein the adhesive substance is designed to have a solid state of aggregation at a first temperature and to go over into a liquid state of aggregation at a second temperature, which is greater than the first temperature.

22. The optoelectronic component as claimed in claim 21, wherein the drill hole is formed as extending conically.

23. A method for processing an optoelectronic component, the method comprising:
providing an optoelectronic component that has a light-emitting diode and a receiving device, at which the light-emitting diode is received; and
applying a fixing device to the receiving device, wherein the fixing device has an adhesive substance in order to be able to adhesively attach the receiving device to a carrier.

24. The method as claimed in claim 23, wherein the fixing device has a spacer that is secured by a first end to the receiving device, and wherein an adhesive substance is arranged at a second end that is opposite from the first end.

25. The method as claimed in claim 24, wherein the receiving device is provided with a clearance before applying the fixing device, wherein a drop of adhesive substance is subsequently arranged in the clearance.

26. The method as claimed in claim 23, wherein, before applying the fixing device, the receiving device is provided with a drill hole, into which an adhesive substance is introduced.

27. The method as claimed in claim 26, wherein the adhesive substance is designed to have a solid state of aggregation at a first temperature and to go over into a liquid state of aggregation at a second temperature, which is greater than the first temperature.

28. The method as claimed in claim 23, further comprising adhesively attaching the receiving device to the carrier.

29. The method as claimed in claim 28, wherein the receiving device includes a hole within an adhesive substance is disposed;
wherein the adhesive substance is designed to have a solid state of aggregation at a first temperature and to go over into a liquid state of aggregation at a second temperature that is greater than the first temperature; and
wherein the adhesively attaching comprises warming the adhesive substance to at least the second temperature, so that the adhesive substance liquefies and runs out of the hole and contacts both the carrier and the receiving device, and subsequently curing the adhesive.

30. A method for equipping a carrier with an optoelectronic component that comprises a light-emitting diode, a receiving device, at which the light-emitting diode is received, wherein the receiving device has a fixing device that comprises an adhesive substance in order to be able to adhesively attach the receiving device to a carrier carrying the receiving device, the method comprising:
arranging the optoelectronic component on the carrier and
fixing the optoelectronic component to the carrier using the adhesive substance.

31. The method as claimed in claim 30, wherein an adhesive substance is received in a drill hole of the receiving device;
wherein the adhesive substance is designed to have a solid state of aggregation at a first temperature and to go over into a liquid state of aggregation at a second temperature, which is greater than the first temperature;
wherein, after the arranging and before the fixing, the method further comprises warming the adhesive substance to at least the second temperature, so that the adhesive substance liquefies and runs out of the drill hole and contacts both the carrier and the receiving device; and
wherein the method further comprises subsequently curing the adhesive.

32. The method as claimed in claim 31, wherein the warming is carried out using infrared radiation.

33. A device for receiving an optoelectronic component that comprises a light-emitting diode, a receiving device at which the light-emitting diode is received, wherein the receiving device has a fixing device that comprises an adhesive substance in order to be able to adhesively attach the receiving device to a carrier carrying the receiving device, the device comprising:
a tape with a number of containers;
wherein the containers are designed for respectively receiving an optoelectronic component;
wherein the containers respectively have a clearance; and
wherein the clearance is designed for contactlessly receiving the adhesive substance of the fixing device.
